(19) United States
(12) Patent Application Publication
(10) Pub. No.: US 2003/0203568 A1
(43) Pub. Date: Oct. 30, 2003

(54) Semiconductor device manufacturing method and semiconductor device

(75) Inventors: Yasunori Sogo, Tokyo (JP); Hidenori Sato, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Mitsubishi Denki Kabushiki Kaisha, Tokyo (JP)

(21) Appl. No.: 10/406,236

(22) Filed: Apr. 4, 2003

Related U.S. Application Data
(62) Division of application No. 10/109,732, filed on Apr. 1, 2002, now abandoned.

(30) Foreign Application Priority Data
Aug. 8, 2001 (JP) 2001-240458

(51) Int. Cl. H01L 21/8242; H01L 21/336

(52) U.S. Cl. 438/253; 438/257; 438/258

(57) ABSTRACT

A method of manufacturing a DRAM/logic-embedded semiconductor device capable of achieving low resistance gate electrodes in the logic device is provided. After gate structures (6a, 6b), in which doped polysilicon films (4a, 4b) and TEOS oxide films (5a, 5b) are stacked on top of the other, are formed in DRAM-forming and logic-forming regions, impurity diffusion regions (7a1, 7a2, 7b) are formed in the respective regions. Then, sidewalls (8a, 8b) are formed on the side surfaces of the gate structures (6a, 6b). After source/drain regions (9) are formed in the logic-forming region, the TEOS oxide film (5b) in the logic forming region is removed. Subsequent silicidation produces cobalt silicide layers (50a1, 50a2, 50b1, 50b2) on the impurity diffusion regions (7a1, 7a2) in the DRAM-forming region and on the source/drain regions (9) and the doped polysilicon films (4b) in the logic-forming region.

### BACKGROUND OF THE INVENTION

1. Field of the Invention

The present invention relates to a manufacturing method and structure for a semiconductor device, and more particularly to a manufacturing method and structure for a DRAM/logic-embedded semiconductor device in which DRAM and logic devices are combined on a single semiconductor substrate.

2. Description of the Background Art

FIGS. 12 to 21 are cross-sectional views illustrating the sequence of process steps of a conventional method of manufacturing a DRAM/logic-embedded semiconductor device. Referring to FIG. 12, initially, an element isolation insulating film 102 is formed in the upper surface of a silicon substrate 101 using the well-known LOCOS or trench isolation technique. In a region where a DRAM device is to be formed (hereinafter referred to as a “DRAM-forming region”), gate structures 106a are formed on the upper surface of the silicon substrate 101. The gate structures 106a each are configured such that a silicon oxide film 103a serving as a gate insulating film, a doped polysilicon film 104a serving as a gate electrode, and a TEOS (tetraethyl orthosilicate) oxide film 105a are stacked one above the other in this order. In a region where a logic device is to be formed (hereinafter referred to as a “logic-forming region”), gate structures 106b are formed on the upper surface of the silicon substrate 101. The gate structures 106b each are configured such that a silicon oxide film 103b serving as a gate insulating film, a doped polysilicon film 104b serving as a gate electrode, and a TEOS oxide film 105b are stacked one above the other in this order. Instead of forming the doped polysilicon films 104a and 104b, undoped polysilicon films may be formed.

Referring to FIG. 13, the upper surface of the silicon substrate 101 is ion implanted with impurities such as phosphorus or arsenic ions in relatively low concentrations, using the gate structures 106a, 106b and the element isolation insulating film 102 as implant masks. This produces n⁻ impurity diffusion regions 107a (indicated by 107a1 and 107a2 in FIG. 13) in the upper surface of the silicon substrate 101 in the DRAM-forming region, and n⁻ impurity diffusion regions 107b in the upper surface of the silicon substrate 101 in the logic-forming region. In FIG. 13, two adjacent ones of the gate structures 106a are shown, in which the impurity diffusion region 107a1 is formed between each of the gate structures 106a and the element isolation insulating film 102 and the impurity diffusion region 107a2 is formed between the gate structures 106a.

Referring to FIG. 14, a silicon nitride film is formed over the whole surface by CVD and then etched by anisotropic dry etching with a high etch rate in the depth direction of the silicon substrate 101. This produces sidewalls 108a on the side surfaces of the gate structures 106a and the sidewalls 108b on the side surfaces of the gate structures 106b.

Referring to FIG. 15, on the upper surface of the silicon substrate 101 in the DRAM-forming region, a photoresist 110 is formed using photolithography techniques, to cover the gate structures 106a and the sidewalls 108a. Then, the upper surface of the silicon substrate 101 is ion implanted with impurities such as phosphorus or arsenic ions in relatively high concentrations, using the gate structures 106b, the element isolation insulating film 102, and the photoresist 110 as implant masks. This produces n⁺ source/drain regions 109 in the upper surface of the silicon substrate 101 in the logic-forming region. The reason why n⁺ source/drain regions are not formed in the DRAM-forming region is for preventing impurities of high concentration from being excessively diffused by heat in the manufacturing process and thereby inducing channel leakage in the DRAM.

Referring to FIG. 16, a cobalt film is formed over the whole surface, for example, by sputtering and then thermally processed to cause a reaction between contact portions of the cobalt and the silicon. This causes silicidation of the upper surface of the source/drain regions 109, thereby forming cobalt silicide (CoSi₂) layers 111. The unreacted cobalt film is subsequently removed.

Referring to FIG. 17, after removal of the photoresist 110, a silicon oxide film 112 serving as an interlayer insulation film is formed over the whole surface by CVD. Then, a photoresist (not shown) having a predetermined pattern of openings is formed on the upper surface of the silicon oxide film 112 by using photolithography techniques. Next, using the photoresist as an etch mask, the silicon oxide film 112 is removed by anisotropic dry etching with a high etch rate in the depth direction of the silicon substrate 101. This produces, in the DRAM-forming region, contact holes 113a (indicated by 113a1 and 113a2 in FIG. 17) that extend from the upper surface of the silicon oxide film 112 to the upper surface of the silicon substrate 101, and in the logic-forming region, contact holes 113b that extend from the upper surface of the silicon oxide film 112 to the upper surfaces of the cobalt silicide layers 111. The contact holes 113a and 113b both have diameters of not more than 0.2 μm.

More specifically, in the DRAM-forming region, the contact holes 113a1 reach the upper surface of the silicon substrate 101 where the impurity diffusion regions 107a1 are formed, and the contact hole 113a2 reaches the upper surface of the silicon substrate 101 where the impurity diffusion region 107a2 is formed. Here, the sidewalls 108a and the TEOS oxide film 105a are used to self-align the contact holes 113a1 and 113a2.

Next, a titanium nitride film is formed to a thickness of about 40 to 50 nm over the whole surface by sputtering. Then, the titanium nitride film that is formed on the upper surface of the silicon oxide film 112 is removed by etching back. The contact holes 113a1, 113a2, and 113b are thus filled respectively with titanium nitride films 114a1, 114a2, and 114b, thereby forming plugs.

If the contact holes 113a and 113b have relatively large diameters, it is possible to form relatively low resistance plugs by first forming a titanium nitride film serving as a barrier metal and then forming a tungsten film by CVD. In the present example, however, both the contact holes 113a and 113b are not more than 0.2 μm in diameter; therefore, a tungsten film cannot be formed after the formation of a titanium nitride film and relatively high resistance plugs are formed only of the titanium nitride film.

Referring to FIG. 18, a silicon nitride film 115 and a silicon oxide film 116 are formed in this order over the whole surface by CVD. The silicon nitride film 115 and the silicon oxide film 116 are then partially removed using photolithography and anisotropic dry etching techniques, whereby recesses 117 are formed. By the formation of the recesses 117, the upper surfaces of the titanium nitride films 114a1 are exposed.

Referring to FIG. 19, DRAM capacitors 121 are formed in the recesses 117. The details are as follows. First, bottom electrodes 118 of the capacitors 121 are formed on the side and bottom surfaces of the recesses 117. The bottom electrodes 118 are formed by forming a Ti film over the whole surface by sputtering, then forming a Ru film over the whole surface by CVD, and then removing the Ti and Ru films that are formed on the silicon oxide film 116 by using photolithography and anisotropic dry etching techniques.

After the formation of the bottom electrodes 118, dielectric films 119 and top electrodes 120 of the capacitors 121 are formed. More specifically, a Ta film is formed over the whole surface by CVD and then oxidized by RTA, thereby to form a Ta₂O₅ film. Then, a Ru film is formed over the whole surface by CVD. By patterning the Ta₂O₅ film and the Ru film using photolithography and anisotropic dry etching techniques, the dielectric films 119 and the top electrodes 120 are formed.

Referring to FIG. 20, a silicon oxide film 122 is formed over the whole surface by CVD. Then, the silicon oxide films 122, 116 and the silicon nitride film 115 are partially removed using photolithography and anisotropic dry etching techniques, thereby to form contact holes 123a and 123b. By the formation of the contact hole 123a, the upper surface of the titanium nitride film 114a2 is exposed, and by the formation of the contact holes 123b, the upper surfaces of the titanium nitride films 114b are exposed.

Referring to FIG. 21, the contact holes 123a and 123b are filled respectively with tungsten plugs 124a and 124b. Then, aluminum wires 125a and 125b that are in contact respectively with the tungsten plugs 124a and 124b are formed on the silicon oxide film 122.

In the above conventional semiconductor device manufacturing method, for self-aligned openings of the contact holes 113a1 and 113a2, the TEOS oxide films 105a and 105b are formed respectively on the doped polysilicon films 104a and 104b. Because the upper surfaces of the doped polysilicon films 104b are covered with the TEOS oxide films 105b, the cobalt silicide layers 111 cannot be formed on the doped polysilicon films 104b during the process step of forming the cobalt silicide layers 111 shown in FIG. 16. This produces relatively high resistance gate electrodes in the logic device.

### SUMMARY OF THE INVENTION

A first aspect of the present invention is directed to a method of manufacturing a semiconductor device, comprising the steps of: (a) preparing a semiconductor substrate having a first region where a memory device is to be formed and a second region where a logic device is to be formed; (b) forming a first gate structure on a main surface in the first region of the semiconductor substrate and a second gate structure on the main surface in the second region of the semiconductor substrate, the first gate structure having a first gate insulating film, a first gate electrode, and a first insulation film stacked in this order, the second gate structure having a second gate insulating film, a second gate electrode, and a second insulation film stacked in this order; (c) forming a first sidewall on a side surface of the first gate structure; (d) removing the second insulation film to expose a main surface of the second gate electrode; (e) forming a first metal-semiconductor compound layer on the main surface of the second gate electrode; (f) forming an interlayer insulation film to cover the first gate structure and the first sidewall; (g) forming a contact hole in the interlayer insulation film in a self-aligned manner by using the first insulation film and the first sidewall, the contact hole reaching the main surface in the first region of the semiconductor substrate; (h) filling the contact hole with a conductive plug; and (i) forming a capacitor in contact with the plug.

According to a second aspect of the present invention, the method of the first aspect further comprises the steps of: (j) forming a second sidewall on a side surface of the second gate structure, the steps (j) and (c) being performed in a single step; and (k) forming a second metal-semiconductor compound layer on an exposed portion of the main surface in the second region of the semiconductor substrate which is not covered with the second sidewall and the second gate structure.

According to a third aspect of the present invention, in the method of the second aspect, the steps (e) and (k) are performed in a single step.

According to a fourth aspect of the present invention, the method of the second or third aspect further comprises the step of: (l) forming a third metal-semiconductor compound layer on an exposed portion of the main surface in the first region of the semiconductor substrate which is not covered with the first sidewall and the first gate structure, the step (l) being performed before the step (f).

According to a fifth aspect of the present invention, in the method of the fourth aspect, the steps (l), (e), and (k) are performed in a single step.

According to a sixth aspect of the present invention, the method of the first aspect further comprises the step of: (j) forming a second metal-semiconductor compound layer on an exposed portion of the main surface in the first region of the semiconductor substrate which is not covered with the first sidewall and the first gate structure, the step (j) being performed before the step (f).

According to a seventh aspect of the present invention, in the method of the sixth aspect, the steps (e) and (j) are performed in a single step.

An eighth aspect of the present invention is directed to a semiconductor device comprising: a semiconductor substrate; a first gate structure which is formed on a main surface in a first region of the semiconductor substrate and which has a first gate insulating film, a first gate electrode, and a first insulation film stacked in this order; a second gate structure which is formed on the main surface in a second region of the semiconductor substrate and which has a second gate insulating film and a second gate electrode stacked in this order; a first sidewall formed on a side surface of the first gate structure; a second sidewall formed on a side surface of the second gate structure to extend beyond the second gate structure; an interlayer insulation film formed to cover the first gate structure and the first sidewall; a contact hole formed in the interlayer insulation film in contact with the first sidewall to reach the main surface in the first region of the semiconductor substrate; a conductive plug formed to fill the contact hole; a capacitor formed in contact with the plug; and a first metal-semiconductor compound layer formed on the second gate electrode.

According to a ninth aspect of the present invention, the semiconductor device of the eighth aspect further comprises a second metal-semiconductor compound layer formed on an exposed portion of the main surface in the second region of the semiconductor substrate which is not covered with the second sidewall and the second gate structure.

According to a tenth aspect of the present invention, the semiconductor device of the ninth aspect further comprises a third metal-semiconductor compound layer formed on an exposed portion of the main surface in the first region of the semiconductor substrate which is not covered with the first sidewall and the first gate structure.

According to an eleventh aspect of the present invention, the semiconductor device of the eighth aspect further comprises a second metal-semiconductor compound layer formed on an exposed portion of the main surface in the first region of the semiconductor substrate which is not covered with the first sidewall and the first gate structure.

In the first aspect of the present invention, the main surface of the second gate electrode is exposed in the step (d), and then in the step (e), the first metal-semiconductor compound layer is formed on the main surface of the second gate electrode. This allows a reduction in the resistance of the second gate electrode in the logic device.

In the second aspect of the present invention, the formation of the second metal-semiconductor compound layer allows a reduction in the resistance of source/drain regions in the logic device.

In the third aspect of the present invention, the number of process steps can be reduced as compared with the cases of individually performing the steps (e) and (k).

In the fourth aspect of the present invention, the formation of the third metal-semiconductor compound layer allows a reduction in the contact resistance of the plug in the memory device.

In the fifth aspect of the present invention, the number of process steps can be reduced as compared with the cases of individually performing the steps (l), (e), and (k).

In the sixth aspect of the present invention, the formation of the second metal-semiconductor compound layer allows a reduction in the contact resistance of the plug in the memory device.

In the seventh aspect of the present invention, the number of process steps can be reduced as compared with the cases of individually performing the steps (e) and (j).

In the eighth aspect of the present invention, the formation of the first metal-semiconductor compound layer on the second gate electrode allows a reduction in the resistance of the second gate electrode in the logic device.

In addition, the second gate structure having the second sidewall can be formed by forming the second sidewall on the side surface of a structure, which is obtained by forming an insulation film corresponding to the first insulation film on the second gate electrode, and then removing the insulation film. Performing, after the removal of the insulation film, the step of forming a metal-semiconductor compound layer on source/drain regions in the logic device can thus produce the first metal-semiconductor compound layer therealong.

In the ninth aspect of the present invention, the presence of the second metal-semiconductor compound layer allows a reduction in the resistance of the source/drain regions in the logic device.

In the tenth aspect of the present invention, the presence of the third metal-semiconductor compound layer allows a reduction in the contact resistance of the plug in the memory device.

In the eleventh aspect of the present invention, the presence of the second metal-semiconductor compound layer allows a reduction in the contact resistance of the plug in the memory device.

An object of the present invention is to solve the conventional problem previously described and to provide a manufacturing method and structure for a DRAM/logic-embedded semiconductor device capable of achieving low resistance gate electrodes in the logic device.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 to 11 are cross-sectional views illustrating the sequence of process steps of a semiconductor device manufacturing method according to a preferred embodiment of the present invention; and

FIGS. 12 to 21 are cross-sectional views illustrating the sequence of process steps of a conventional semiconductor device manufacturing method.

### DESCRIPTION OF THE PREFERRED EMBODIMENTS

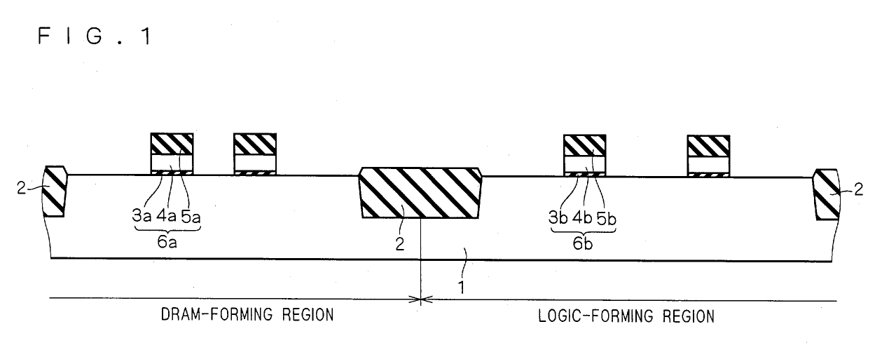

FIGS. 1 to 11 are cross-sectional views illustrating the sequence of process steps of a semiconductor device manufacturing method according to a preferred embodiment of the present invention. Referring to FIG. 1, initially, an element isolation insulating film 2 is formed in the upper surface of a silicon substrate 1 using the well-known LOCOS or trench isolation technique. Then, a silicon oxide film, a doped polysilicon film, and a TEOS oxide film are formed in this order over the whole surface, for example, by thermal oxidation or CVD. Those films are then patterned using photolithography and anisotropic dry etching techniques, whereby gate structures 6a are formed on the upper surface of the silicon substrate 1 in a DRAM-forming region and gate structures 6b are formed on the upper surface of the silicon substrate 1 in a logic-forming region. The gate structures 6a each are configured such that a silicon oxide film 3a serving as a gate insulating film, a doped polysilicon film 4a serving as a gate electrode, and a TEOS oxide film 5a are stacked one above the other in this order. The gate structures 6b each are configured such that a silicon oxide film 3b serving as a gate insulating film, a doped polysilicon film 4b serving as a gate electrode, and a TEOS oxide film 5b are stacked one above the other in this order. Instead of forming the doped polysilicon films 4a and 4b, undoped polysilicon films may be formed.

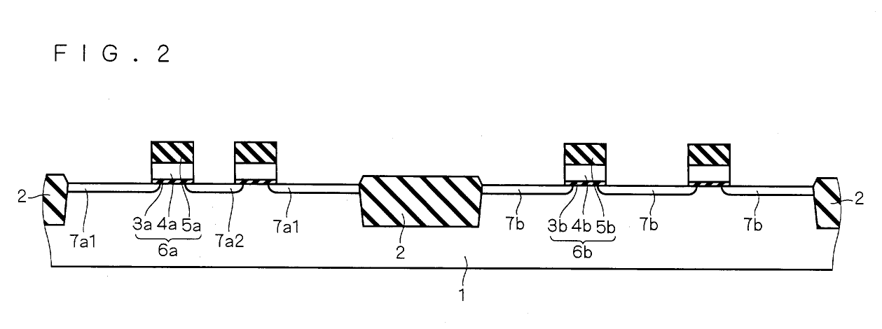

Referring to FIG. 2, the upper surface of the silicon substrate 1 is ion implanted with impurities such as phosphorus or arsenic ions in relatively low concentrations, using the gate structures 6a, 6b and the element isolation insulating film 2 as implant masks. This produces n⁻ impurity diffusion regions 7a (indicated by 7a1, 7a2 in FIG. 2) in the upper surface of the silicon substrate 1 in the DRAM-forming region, and n⁻ impurity diffusion regions 7b in the upper surface of the silicon substrate 1 in the logic-forming region. In FIG. 2, two adjacent ones of the gate structures 6a are shown, in which the impurity diffusion region 7a1 is formed between each of the gate structures 6a and the element isolation insulating film 2 and the impurity diffusion region 7a2 is formed between the gate electrodes 6a.

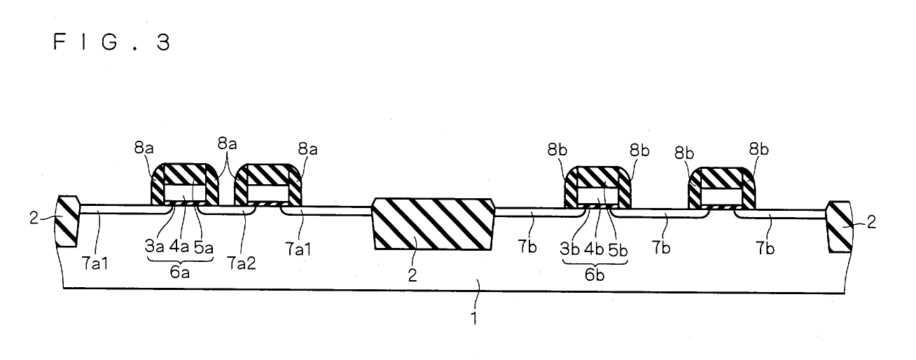

Referring to FIG. 3, a silicon nitride film is formed over the whole surface by CVD and then etched by anisotropic dry etching with a high etch rate in the depth direction of the silicon substrate 1. This produces sidewalls 8a on the side surfaces of the gate structures 6a and sidewalls 8b on the side surfaces of the gate structures 6b.

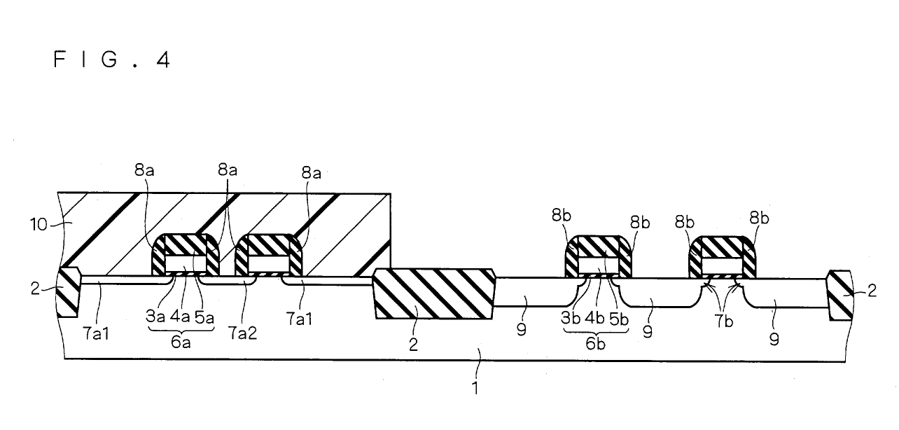

Referring to FIG. 4, by using photolithography techniques, a photoresist 10 is formed on the upper surface of the silicon substrate 1 in the DRAM-forming region to cover the gate structures 6a and the sidewalls 8a. Then, the upper surface of the silicon substrate 1 is ion implanted with impurities such as phosphorus or arsenic ions in relatively high concentrations, using the gate structures 6b, the element isolation insulating film 2, and the photoresist 10 as implant masks. This produces n⁺ source/drain regions 9 in the upper surface of the silicon substrate 1 in the logic-forming region.

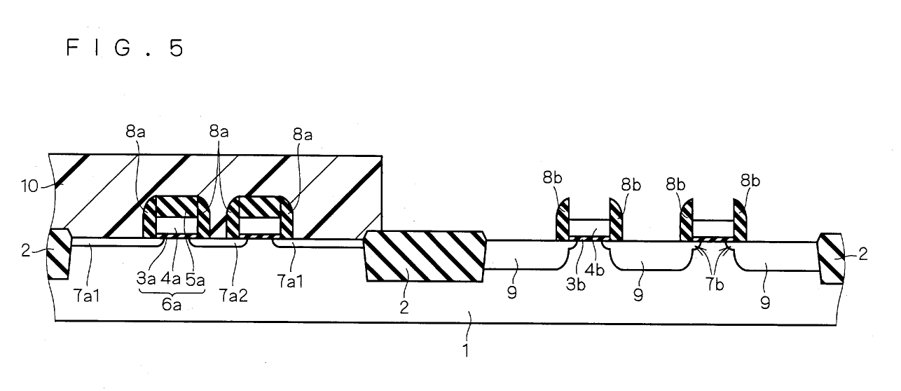

Referring to FIG. 5, the TEOS oxide film 5b is removed by etching performed under such conditions that only the TEOS oxide film is removed without removal of the silicon nitride film and silicon. Thereby the upper surfaces of the doped polysilicon films 4b are exposed. As shown in FIG. 5, the side surfaces of the gate structures formed of the silicon oxide films 3b and the doped polysilicon films 4b have the sidewalls 8b, which extend beyond the gate structures.

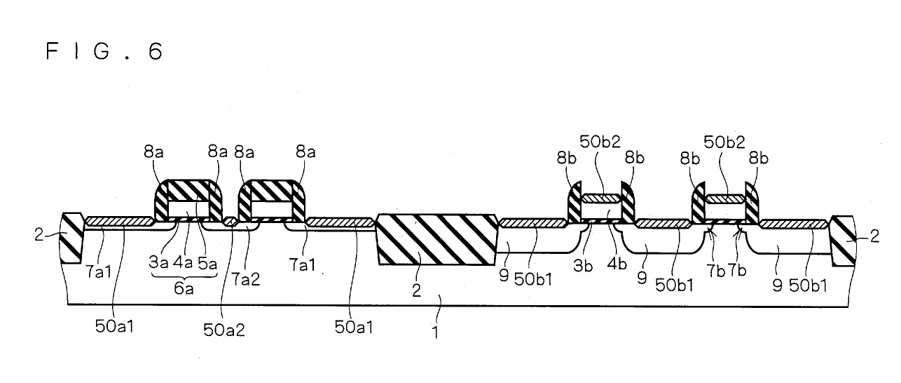

Referring to FIG. 6, after removal of the photoresist 10, a cobalt film is formed over the whole surface, for example, by sputtering and then thermally processed to cause a reaction between contact portions of the cobalt and the silicon. This causes silicidation of exposed portions of the upper surfaces of the impurity diffusion regions 7a1 and 7a2 that are not covered with the sidewalls 8a and thereby produces cobalt silicide layers 50a1 and 50a2. Also, the upper surfaces of the source/drain regions 9 are silicided to form cobalt silicide layers 50b1, and the upper surfaces of the doped polysilicon films 4b are silicided to form cobalt silicide layers 50b2. The unreacted cobalt film is subsequently removed.

Instead of forming the above cobalt film after the removal of the photoresist 10, a titanium film may be formed. In this case, not the cobalt silicide layers 50a1, 50a2, 50b1, and 50b2 but titanium silicide layers are formed.

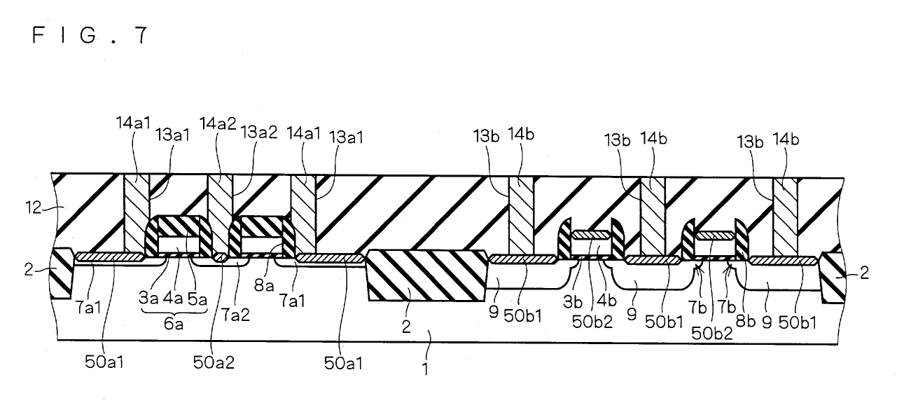

Referring to FIG. 7, a silicon oxide film 12 serving as an interlayer insulation film is formed over the whole surface by CVD. Then, a photoresist (not shown) having a predetermined pattern of openings is formed on the upper surface of the silicon oxide film 12 by using photolithography techniques. Using the photoresist as an etch mask, the silicon oxide film 12 is removed by anisotropic dry etching with a high etch rate in the depth direction of the silicon substrate 1. This produces, in the DRAM-forming region, contact holes 13a1 and 13a2 that extend from the upper surface of the silicon oxide film 12 respectively to the upper surfaces of the cobalt silicide layers 50a1 and 50a2, and in the logic-forming region, contact holes 13b that extend from the upper surface of the silicon oxide film 12 to the upper surfaces of the cobalt silicide layers 50b1. Here, the sidewalls 8a and the TEOS oxide films 5a are used to self-align the contact holes 13a1 and 13a2. Both the contact holes 13a1 and 13a2 are thus in contact with the sidewalls 8a. The contact holes 13a and 13b both have diameters of not more than 0.2 μm.

Next, a titanium nitride film is formed to a thickness of about 40 to 50 nm over the whole surface by sputtering. Then, the titanium nitride film that is formed on the upper surface of the silicon oxide film 12 is removed by etching back. The contact holes 13a1, 13a2, and 13b are thus filled respectively with titanium nitride films 14a1, 14a2, and 14b, thereby forming plugs.

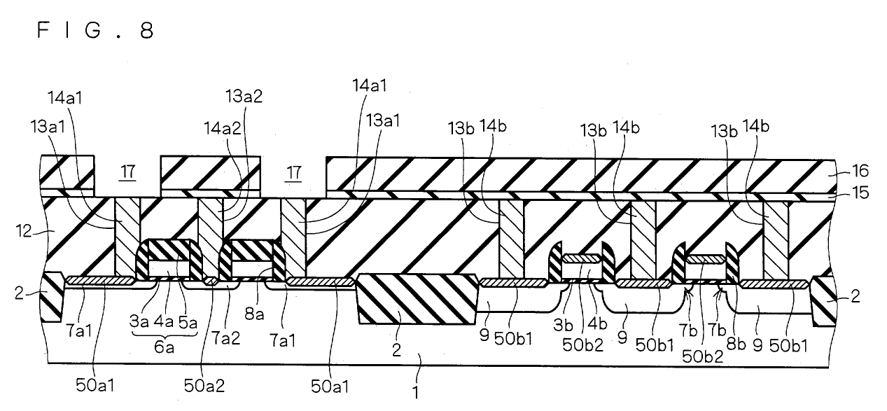

Referring to FIG. 8, a silicon nitride film 15 and a silicon oxide film 16 are formed in this order over the whole surface by CVD. The silicon nitride film 15 and the silicon oxide film 16 are then partially removed using photolithography and anisotropic dry etching techniques, whereby recesses 17 are formed. By the formation of the recesses 17, the upper surfaces of the titanium nitride films 14a1 are exposed.

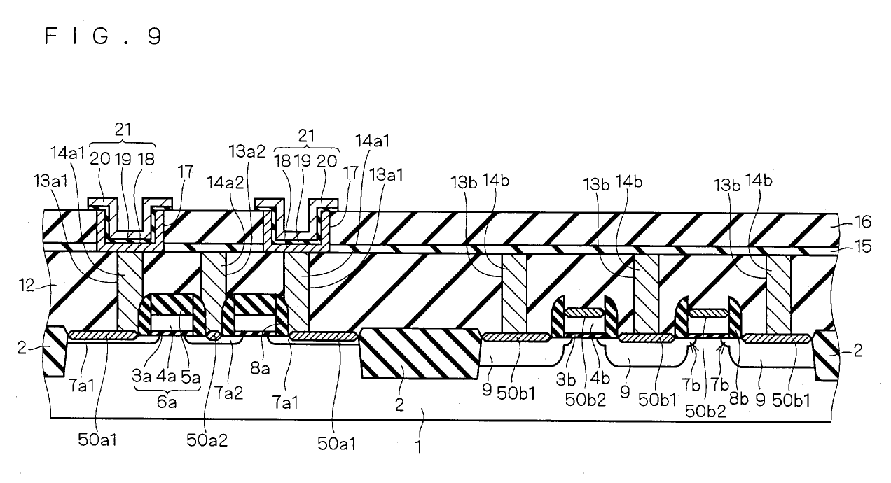

Referring to FIG. 9, DRAM capacitors 21 are formed in the recesses 17. The details are as follows. First, bottom electrodes 18 of the capacitors 21 are formed on the side and bottom surfaces of the recesses 17. The bottom electrodes 18 are formed by first forming a Ti film over the whole surface by sputtering, then forming a Ru film over the whole surface by CVD, and then removing the Ti and Ru films that are formed on the silicon oxide film 16 by using photolithography and anisotropic dry etching techniques.

After the formation of the bottom electrodes 18, dielectric films 19 and top electrodes 20 of the capacitors 21 are formed. More specifically, a Ta film is formed over the whole surface by CVD and then oxidized by RTA, thereby to form a Ta₂O₅ film. Then, a Ru film is formed over the whole surface by CVD. By patterning the Ta₂O₅ film and the Ru film using photolithography and anisotropic dry etching techniques, the dielectric films 19 and the top electrodes 20 are formed.

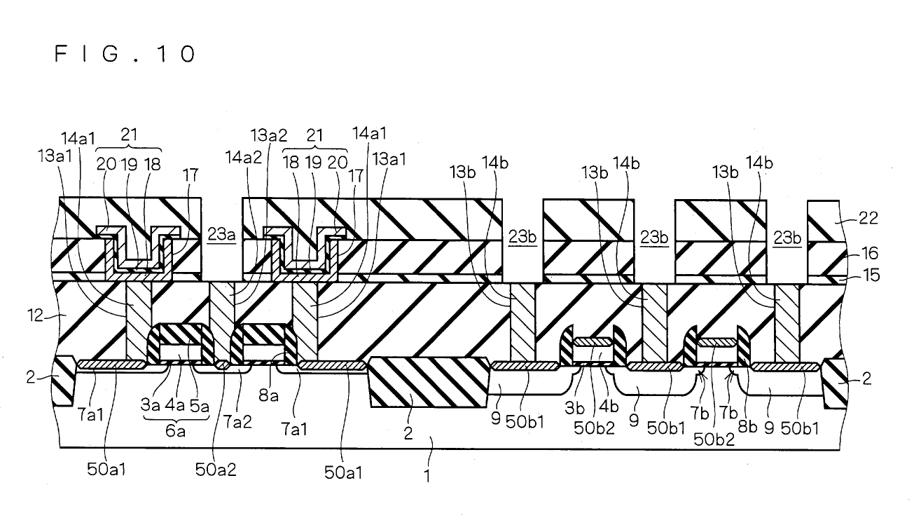

Referring to FIG. 10, a silicon oxide film 22 is formed over the whole surface by CVD. Then, the silicon oxide films 22, 16 and the silicon nitride film 15 are partially removed using photolithography and anisotropic dry etching techniques, thereby forming contact holes 23a and 23b. By the formation of the contact hole 23a, the upper surface of the titanium nitride film 14a2 is exposed and by the formation of the contact holes 23b, the upper surfaces of the titanium nitride films 14b are exposed.

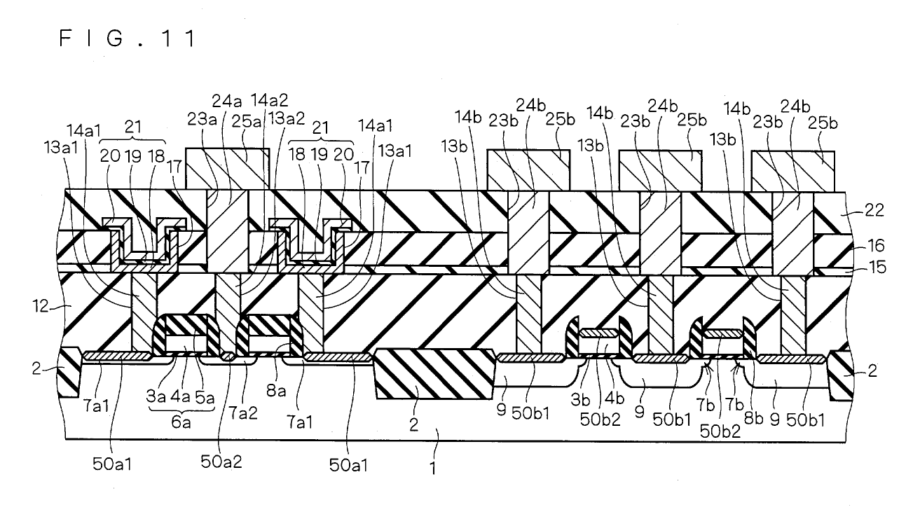

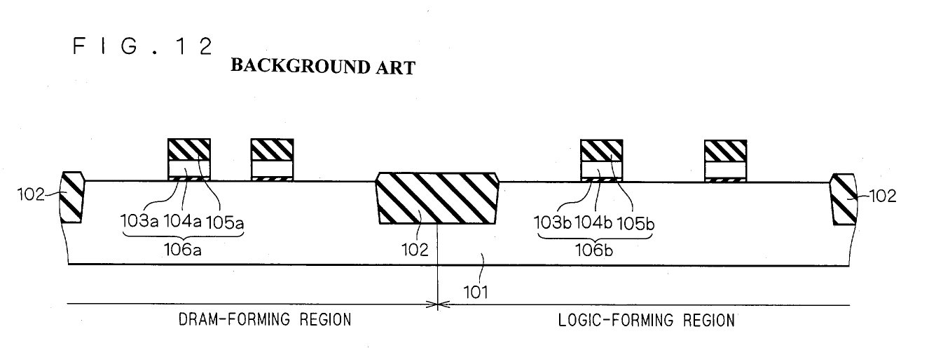

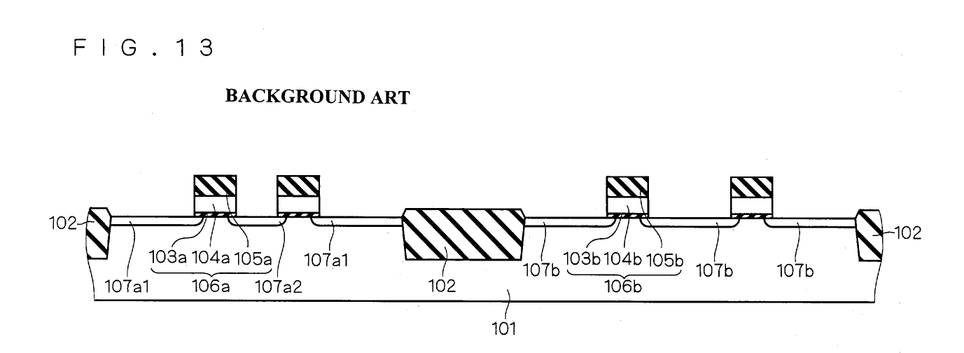

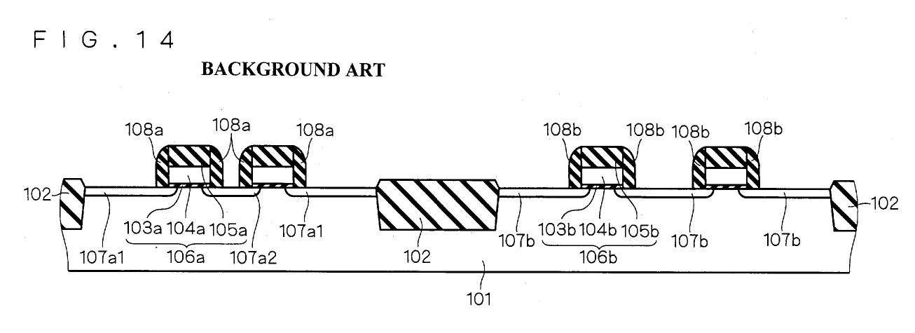

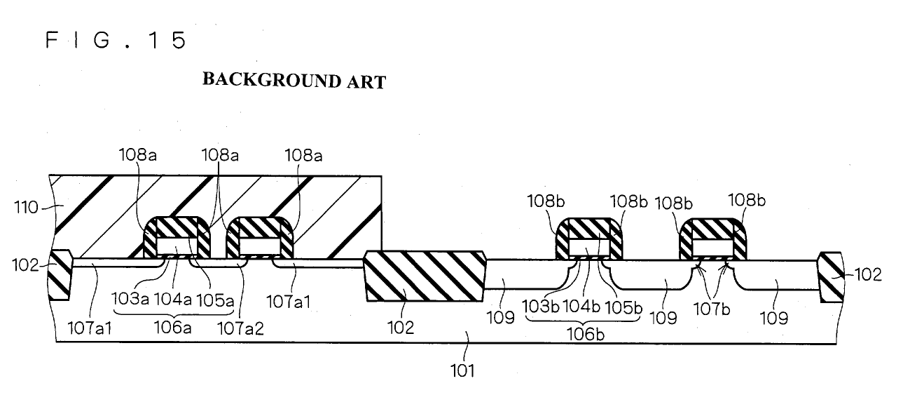

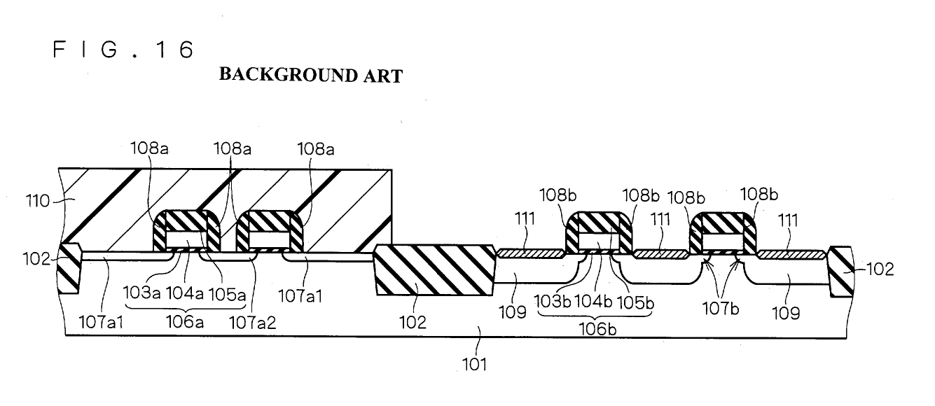

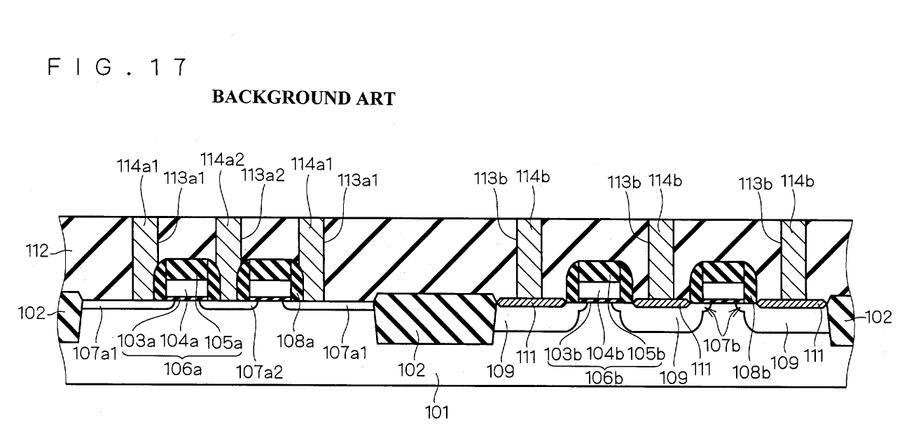

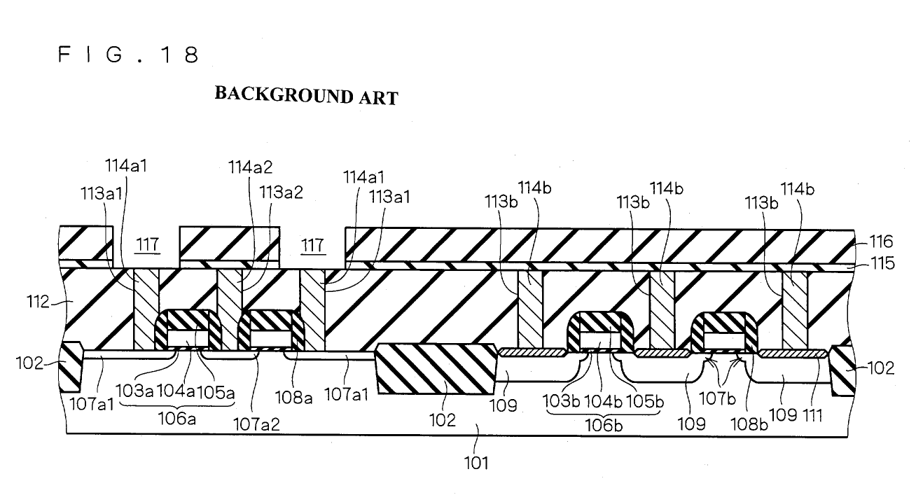

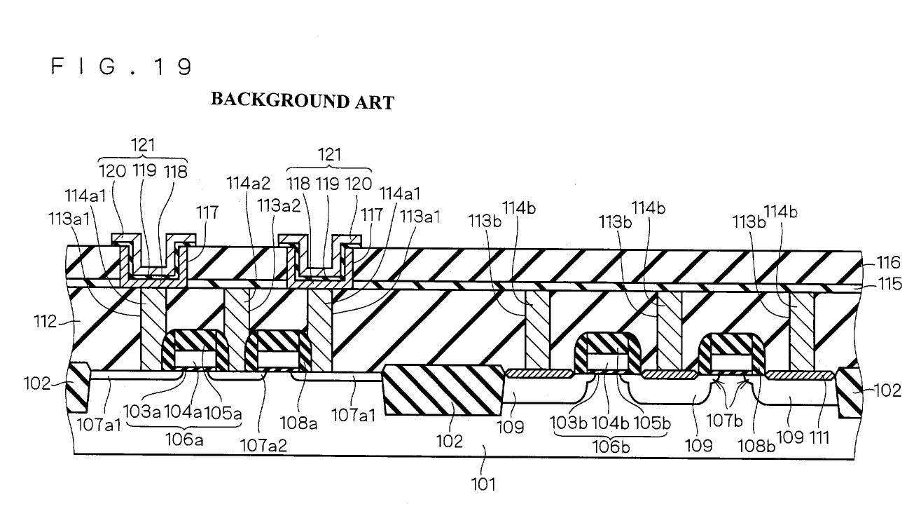

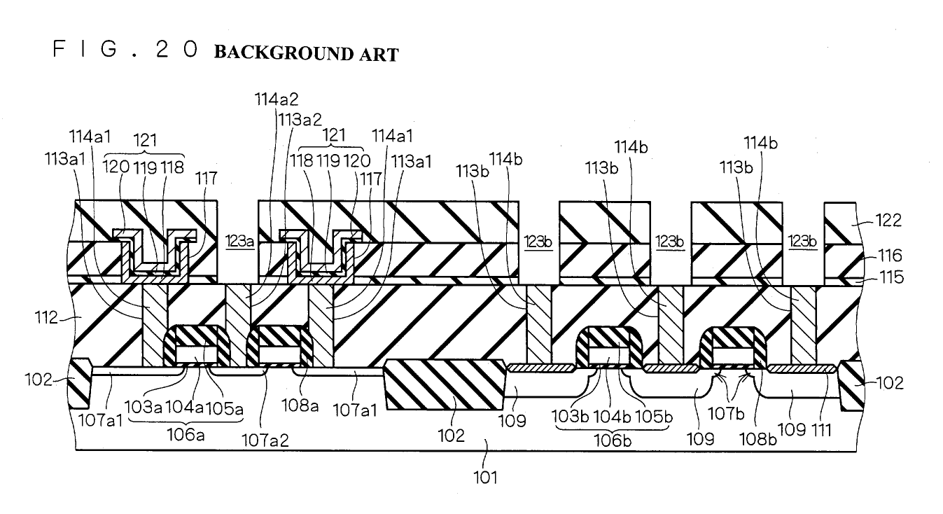

Referring to FIG. 11, the contact holes 23a and 23b are filled respectively with tungsten plugs 24a and 24b. Then, aluminum wires 25a and 25b that are in contact respectively with the tungsten plugs 24a and 25b are formed on the silicon oxide film 22. Through the above process steps, as shown in FIG. 11, a DRAM device is formed in the DRAM-forming region and a logic device is formed in the logic-forming region.

In the semiconductor device and the manufacturing method thereof according the preferred embodiment of the present invention, the upper surfaces of the doped polysilicon films 4b are exposed by the removal of the TEOS oxide film 5b in the process step of FIG. 5, and then silicon silicidation occurs in the process step of FIG. 6. This allows the cobalt silicide layers 50b2 to be formed on the upper surfaces of the doped polysilicon films 4b, during the process step of forming the cobalt silicide layers 50a1 and 50a2 in the DRAM-forming region and forming the cobalt silicide layers 50b1 in the logic-forming region. This achieves low resistance gate electrodes in the logic device.

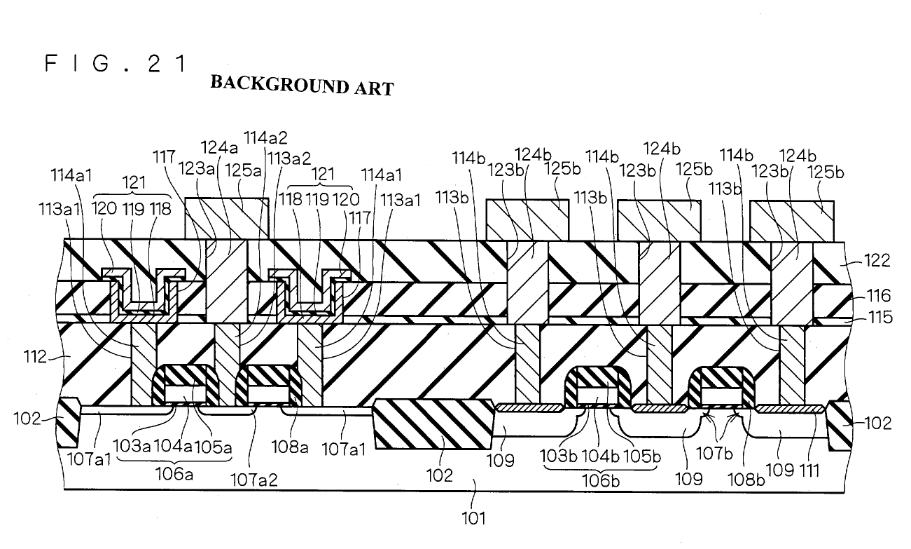

Further, in the DRAM-forming region, the cobalt silicide layers 50a1 and 50a2 are formed respectively on the impurity diffusion regions 7a1 and 7a2; therefore, the titanium nitride films 14a1 and 14a2 are formed in contact respectively with the cobalt silicide layers 50a1 and 50a2, not with the n⁻ impurity diffusion layers 7a1 and 7a2. This reduces contact resistances of the titanium nitride films 14a1 and 14a2, as compared with those in the conventional semiconductor device shown in FIG. 21.

While the invention has been shown and described in detail, the foregoing description is in all aspects illustrative and not restrictive. It is therefore understood that numerous modifications and variations can be devised without departing from the scope of the invention.

What is claimed is:

1. A method of manufacturing a semiconductor device, comprising the steps of:
(a) preparing a semiconductor substrate having a first region where a memory device is to be formed and a second region where a logic device is to be formed;
(b) forming a first gate structure on a main surface in said first region of said semiconductor substrate and a second gate structure on said main surface in said second region of said semiconductor substrate, said first gate structure having a first gate insulating film, a first gate electrode, and a first insulation film stacked in this order, said second gate structure having a second gate insulating film, a second gate electrode, and a second insulation film stacked in this order;
(c) forming a first sidewall on a side surface of said first gate structure;
(d) removing said second insulation film to expose a main surface of said second gate electrode;
(e) forming a first metal-semiconductor compound layer on said main surface of said second gate electrode;
(f) forming an interlayer insulation film to cover said first gate structure and said first sidewall;
(g) forming a contact hole in said interlayer insulation film in a self-aligned manner by using said first insulation film and said first sidewall, said contact hole reaching said main surface in said first region of said semiconductor substrate;
(h) filling said contact hole with a conductive plug; and
(i) forming a capacitor in contact with said plug.

2. The method according to claim 1, further comprising the steps of:
(j) forming a second sidewall on a side surface of said second gate structure, said steps (j) and (c) being performed in a single step; and
(k) forming a second metal-semiconductor compound layer on an exposed portion of said main surface in said second region of said semiconductor substrate which is not covered with said second sidewall and said second gate structure.

3. The method according to claim 2, wherein
said steps (e) and (k) are performed in a single step.

4. The method according claim 2, further comprising the step of:
(l) forming a third metal-semiconductor compound layer on an exposed portion of said main surface in said first region of said semiconductor substrate which is not covered with said first sidewall and said first gate structure,
said step (l) being performed before said step (f).

5. The method according to claim 4, wherein
said steps (l), (e), and (k) are performed in a single step.

6. The method according to claim 2, further comprising the steps of:
(x) forming a first impurity introduced region of relatively low concentration in an exposed portion of said main surface in said first and second regions of said semiconductor substrate which is not covered with said first and second gate structures,
said step (x) being performed between said steps (b) and (c); and
(y) forming a second impurity introduced region of relatively high concentration in an exposed portion of said main surface in said second region of said semiconductor substrate which is not covered with said second sidewall and said second gate structure,
said step (y) being performed between said steps (j) and (k).

7. The method according to claim 1, further comprising the step of:
(j) forming a second metal-semiconductor compound layer on an exposed portion of said main surface in said first region of said semiconductor substrate which is not covered with said first sidewall and said first gate structure,
said step (j) being performed before said step (f).

8. The method according to claim 7, wherein
said steps (e) and (j) are performed in a single step.

9. The method according to claim 1, wherein
said second gate electrode is made of a doped polysilicon film,
said second insulation film is made of a TEOS oxide film,
said first sidewall is made of a silicon nitride film, and
in said step (d), said second insulation film is removed by etching performed under such conditions that a TEOS oxide film is removed without removal of a silicon nitride film and silicon.

10. A semiconductor device comprising:
a semiconductor substrate;
a first gate structure which is formed on a main surface in a first region of said semiconductor substrate and which has a first gate insulating film, a first gate electrode, and a first insulation film stacked in this order;
a second gate structure which is formed on said main surface in a second region of said semiconductor substrate and which has a second gate insulating film and a second gate electrode stacked in this order;
a first sidewall formed on a side surface of said first gate structure;
a second sidewall formed on a side surface of said second gate structure to extend beyond said second gate structure;
an interlayer insulation film formed to cover said first gate structure and said first sidewall;
a contact hole formed in said interlayer insulation film in contact with said first sidewall to reach said main surface in said first region of said semiconductor substrate;
a conductive plug formed to fill said contact hole;
a capacitor formed in contact with said plug; and
a first metal-semiconductor compound layer formed on said second gate electrode.

11. The semiconductor device according to claim 10, further comprising:
a second metal-semiconductor compound layer formed on an exposed portion of said main surface in said second region of said semiconductor substrate which is not covered with said second sidewall and said second gate structure.

12. The semiconductor device according to claim 11, further comprising:
a third metal-semiconductor compound layer formed on an exposed portion of said main surface in said first region of said semiconductor substrate which is not covered with said first sidewall and said first gate structure.

13. The semiconductor device according to claim 10, further comprising:
a second metal-semiconductor compound layer formed on an exposed portion of said main surface in said first region of said semiconductor substrate which is not covered with said first sidewall and said first gate structure.

14. The semiconductor device according to claim 10, further comprising:
a first impurity introduced region of relatively low concentration formed in an exposed portion of said main surface in said first and second regions of said semiconductor substrate which is not covered with said first and second gate structures; and
a second impurity introduced region of relatively high concentration formed in an exposed portion of said main surface in said second region of said semiconductor substrate which is not covered with said second sidewall and said second gate structure.
